(19) United States
(12) Patent Application Publication
(10) Pub. No.: US 2021/0249284 A1
(43) Pub. Date: Aug. 12, 2021

(54) FAST RESPONSE DUAL-ZONE PEDESTAL ASSEMBLY FOR SELECTIVE PRECLEAN

(71) Applicant: Applied Materials, Inc., Santa Clara, CA (US)

(72) Inventors: Chaitanya A. PRASAD, Bangalore (IN); Daniel C. GLOVER, Danville, CA (US); Naman APURVA, Patna (IN)

(21) Appl. No.: 16/789,206

(22) Filed: Feb. 12, 2020

(51) Int. Cl. H01L 21/67; H01L 21/687; F27D 5/00; B23K 1/00

(52) U.S. Cl. CPC H01L 21/67103; H01L 21/67248; H01L 21/68792; H01L 21/68785; B23K 2103/10; B23K 1/0008; H01L 21/67028; H01L 21/67069; H01L 21/68757; F27D 5/0037

(57) ABSTRACT

A substrate support pedestal connectable to a shaft includes a thermally conductive body, a first fluid channel disposed within an outer zone of the thermally conductive body, and a second fluid channel disposed within an inner zone of the thermally conductive body. The first fluid channel and the second fluid channel are not in fluid communication with each other and are thermally isolated from each other by a thermal barrier within the substrate support channel.

### FIELD

Embodiments described herein are generally related to a substrate support pedestal for the use in a pre-cleaning chamber, and more specifically, a substrate support pedestal that allows rapid heating and cooling of a substrate disposed on the substrate support pedestal and independent temperature control of an inner zone and an outer zone of the substrate support pedestal.

### BACKGROUND

Integrated circuits are fabricated by processes which produce intricately patterned material layers on substrate surfaces. Surfaces of substrates, e.g., crystalline silicon and epitaxial silicon layers, may be oxidized and/or susceptible to foreign contaminations, e.g. carbon or oxygen present during fabrication processes, which may directly impact the final product. Thus, substrate surfaces are routinely pre-cleaned before the fabrication processes.

Conventionally, pre-cleaning processes are performed in a vacuum processing chamber having a substrate support pedestal, on which a substrate is disposed. Temperature fluctuations may occur across the substrate surface. For example, an edge of the substrate support pedestal may have higher temperature than a center of the substrate support pedestal due to heated chamber walls of the vacuum processing chamber, causing an edge of the substrate to be rolled off. These temperature fluctuations may affect fabrication processes performed on or to the substrate, which may often reduce the uniformity of deposited films or etched structures along the substrate. Depending on the degree of variation along the surface of the substrate, device failure may occur due to the inconsistencies produced by the applications.

Additionally, since a conventional substrate support pedestal that is made from ceramic material to prevent metal contamination is poor in conducting heat, temperature control of the substrate support pedestal is inefficient and time-consuming.

Therefore, there is a need in the art for an improved substrate support pedestal for use in a pre-cleaning chamber.

### SUMMARY

In one embodiment, a substrate support pedestal connectable to a shaft includes a thermally conductive body, a first fluid channel disposed within an outer zone of the thermally conductive body, and a second fluid channel disposed within an inner zone of the thermally conductive body. The first fluid channel and the second fluid channel are not in fluid communication with each other and are thermally isolated from each other by a thermal barrier within the substrate support pedestal.

In another embodiment, a substrate support pedestal assembly includes a shaft including a first pair of cooling tubes and a second pair of cooling tubes, where the first pair of cooling tubes are configured to be fluidly coupled to a first heated fluid source and the second pair of cooling tubes are configured to be fluidly coupled to a second heated fluid source, and a substrate support pedestal coupled to the shaft, the substrate support pedestal including a first fluid channel in fluid communication with the first pair of cooling tubes and a second fluid channel in fluid communication with the second pair of cooling tubes. The first fluid channel is configured to circulate a first heat exchange fluid at a first temperature in an outer zone of the substrate support pedestal, and the second fluid channel is configured to circulate a second heat exchange fluid at a second temperature that is different from the first temperature in an inner zone of the substrate support pedestal disposed within the outer zone.

In yet another embodiment, a processing chamber includes a chamber body, a shaft disposed within the chamber body, the shaft including a first pair of cooling tubes and a second pair of cooling tubes, where the first pair of cooling tubes are configured to be fluidly coupled to a first heated fluid source and the second pair of cooling tubes are configured to be fluidly coupled to a second heated fluid source, a substrate support pedestal disposed within the chamber body and coupled to the shaft, the substrate support pedestal including a first fluid channel disposed within an outer zone of the substrate support pedestal and in fluid communication with the first pair of cooling tubes and a second fluid channel disposed within an inner zone of the substrate support pedestal and in fluid communication with the second pair of cooling tubes, where the first fluid channel is configured to circulate a first heat exchange fluid at a first temperature in an outer zone of the substrate support pedestal, and the second fluid channel is configured to circulate a second heat exchange fluid at a second temperature that is different from the first temperature in an inner zone of the substrate support pedestal disposed within the outer zone, and a controller configured to determine temperatures of the outer zone and the inner zone of the substrate support pedestal, and adjust the first temperature and the second temperature based on the determined temperatures of the outer zone and the inner zone of the substrate support pedestal.

### BRIEF DESCRIPTION OF THE DRAWINGS

Implementations of the present disclosure, briefly summarized above and discussed in greater detail below, can be understood by reference to the illustrative implementations of the disclosure depicted in the appended drawings. It is to be noted, however, that the appended drawings illustrate only typical implementations of this disclosure and are therefore not to be considered limiting of its scope, for the disclosure may admit to other equally effective implementations.

FIG. 1 depicts a cross sectional view of a pre-cleaning processing chamber in accordance with some embodiments of the present disclosure.

FIG. 2A depicts a cross sectional top view of a dual-zone heater within a dual-zone fast response pedestal in accordance with some embodiments of the present disclosure.

FIG. 2B depicts a schematic side view of a dual-zone fast response pedestal in accordance with some embodiments of the present disclosure.

FIG. 3A depicts a side view of a substrate support assembly that includes the dual-zone fast response pedestal in accordance with some embodiments of the present disclosure.

FIG. 3B depicts a top view of a chiller plate within a dual-zone fast response pedestal in accordance with some embodiments of the present disclosure.

FIG. 4 is a flow diagram of one embodiment of a method for controlling temperature of a substrate supporting surface of a dual-zone fast response substrate support pedestal in accordance with one implementation of the present disclosure.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

Embodiments described herein are generally related to a substrate support pedestal for use in a pre-cleaning chamber, and more specifically, a substrate support pedestal that allows rapid heating and cooling of a substrate disposed on the substrate support pedestal and independent temperature control of an inner zone and an outer zone of the substrate support pedestal.

Substrate support pedestals described herein are made of metal plates and a ceramic coating on the top most metal plate. Thus, heating and cooling of the substrate support pedestals are efficient while contamination of a substrate disposed on the substrate support pedestal is prevented due to the ceramic coating. The substrate support pedestals described herein further include heaters and cooling fluid channels that are temperature-controlled independently for an inner zone and an outer zone of the substrate support pedestal, and thus a substrate residing on the substrate support pedestal can be maintained at a more uniform or desired offset temperature profile across the entire surface.

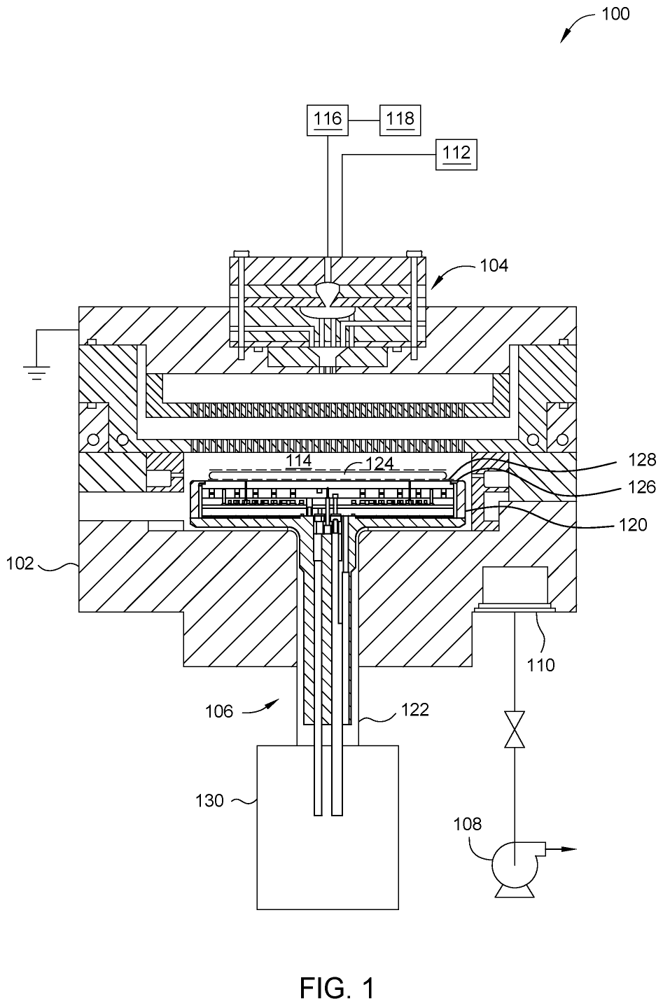

FIG. 1 is a cross sectional view of a pre-cleaning processing chamber 100 that is adapted to remove contaminants, such as oxides, from a surface of a substrate. Exemplary processing chambers that can be adapted to perform a reducing process include Siconi™ processing chambers, available from Applied Materials, Inc., of Santa Clara, Calif. Chambers from other manufacturers may also be adapted to benefit from the invention disclosed herein.

The processing chamber 100 may be particularly useful for performing a thermal or plasma-based cleaning process and/or a plasma assisted dry etch process. The processing chamber 100 includes a chamber body 102, a lid assembly 104, and a substrate support assembly 106. The lid assembly 104 is disposed at an upper end of the chamber body 102, and the substrate support assembly 106 is at least partially disposed within the chamber body 102. A vacuum system including a vacuum pump 108 and a vacuum port 110 can be used to remove gases from processing chamber 100. The vacuum port 110 is disposed in the chamber body 102, and the vacuum pump 108 is coupled to the vacuum port 110. The processing chamber 100 also includes the controller 112 for controlling processes within the processing chamber 100. The controller 112 may include a central processing unit (CPU), memory, and support circuits (or I/O). The CPU may be one of any form of computer processors that are used in industrial settings for controlling various processes and hardware (e.g., pattern generators, motors, and other hardware) and monitor the processes (e.g., processing time and substrate position or location). The CPU may include a real-time proportional-integral-derivative (PID) controller that controls a solid-state relay (SSR) drive to supply power to inline heaters for inner and outer fluid channels and constantly monitors and maintain temperatures of an inner zone and an outer zone of substrate support assembly 106. The memory is connected to the CPU, and may be one or more of a readily available memory, such as random access memory (RAM), read only memory (ROM), floppy disk, hard disk, or any other form of digital storage, local or remote. Software instructions, algorithms and data can be coded and stored within the memory for instructing the CPU. The support circuits (not shown) are also connected to the CPU for supporting the processor in a conventional manner. The support circuits may include conventional cache, power supplies, clock circuits, input/output circuitry, subsystems, and the like. A program (or computer instructions) readable by the controller determines which tasks are performable on a substrate. The program may be software readable by the controller and may include code to monitor and control, for example, the processing time and substrate position or location. The program includes software to run communication and controls of the PID controller and the SSR drive.

The lid assembly 104 includes a plurality of stacked components bonded, welded, fused, or otherwise coupled with each other and configured to provide precursor gases and/or a plasma to a processing region 114 within the processing chamber 100. The lid assembly 104 may be connected to a remote plasma source 116 to generate plasma-byproducts that then pass through the remainder of the lid assembly 104. The remote plasma source 116 is coupled to a gas source 118 (or the gas source 118 is coupled directly to the lid assembly 104 in the absence of the remote plasma source 116). The gas source 118 may include helium, argon, or other inert gas that is energized into a plasma that is provided to the lid assembly 104. In some embodiments, the gas source 118 may include process gases to be activated for reaction with a substrate in the processing chamber 100.

The substrate support assembly 106 includes a dual-zone fast response substrate support pedestal (also referred to as “dual-zone fast response pedestal” or simply as “pedestal” hereinafter) 120 and a shaft 122 that is coupled to the dual-zone fast response pedestal 120. During processing, a substrate 124 may be disposed on a top surface 126 of the pedestal 120 of the substrate support assembly 106. In some embodiments, the top surface 126 of the pedestal 120 is covered with a ceramic coating 128 to prevent metal contamination of the substrate 124. Suitable ceramic coatings include aluminum oxide, aluminum nitride, silica, silicon, yttria, YAG, or other non-metallic coating materials. The coating 128 has a thickness in the range of 50 microns to 1000 microns. The substrate 124 is configured to be vacuum chucked against the ceramic coating 128 disposed on the top surface 126 during processing.

The pedestal 120 is coupled to an actuator 130 by the shaft 122 which extends through a centrally-located opening formed in a bottom of the chamber body 102. The actuator 130 may be flexibly sealed to the chamber body 102 by bellows (not shown) that prevent vacuum leakage around the shaft 122. The actuator 130 allows the pedestal 120 to be moved vertically within the chamber body 102 between one or more processing positions, and a release or transfer position. The transfer position is slightly below the opening of a slit valve formed in a sidewall of the chamber body 102 to allow the substrate 124 to be robotically transfer into and out of the processing chamber 100.

In some process operations, the substrate 124 may be spaced from the top surface 126 by lift pins to perform additional thermal processing operations, such as performing an annealing step. The substrate 124 may be lowered to be placed directly in contact with the pedestal 120 to promote cooling of the substrate 124.

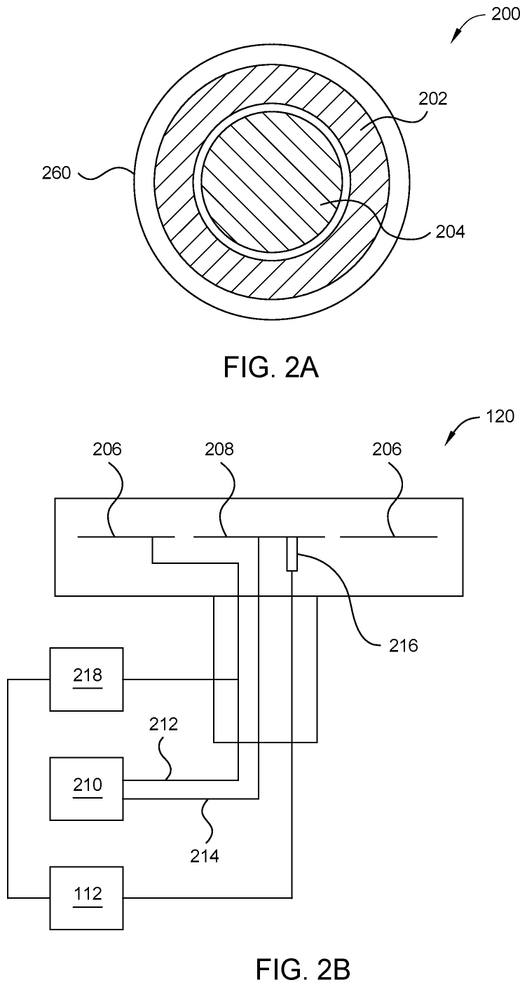

FIG. 2A depicts a cross sectional top view of a dual-zone heater 200 within the dual-zone fast response pedestal 120 in accordance with some embodiments of the present invention. FIG. 2B depicts a schematic side view of the dual-zone fast response pedestal 120 in accordance with some embodiments of the present invention. In some embodiments, the dual-zone heater 200 has heater elements arranged into at least a first zone 202 and a second zone 204 within the pedestal 120, as depicted in FIG. 2A. In some embodiments, the heater elements 206 in the first zone 202 and the heater elements 208 in the second zone 204 are connected to a power source 210, as depicted in FIG. 2B. In some embodiments, as depicted in FIGS. 2A and 2B, the first zone 202 is an outer zone and the second zone 204 is an inner zone disposed within the outer zone. The inner and outer zones may substantially correspond to inner and outer portions of a substrate to be supported on the pedestal 120. In some embodiments, the power source 210 is an about 190 to about 240 VAC, or about 208 VAC power source. Power sources of other sizes may also be used dependent upon the application and design of the apparatus. In some embodiments, the power source 210 runs at a 60 Hz cycle. In some embodiments, as depicted in FIG. 2B, the power source 210 supplies power via a first power feed 212 to the first zone 202 and supplies power via a second power feed 214 to the second zone 204.

The pedestal 120 includes a thermocouple 216 embedded in the second zone 204. The thermocouple 216 is connected to the controller 112, which is further connected to the power source 210. The controller 112 determines the temperature of the second zone 204 of the pedestal 120 using the thermocouple 216.

The temperature of the first zone 202 of the pedestal 120 can be determined by first measuring the current and the voltage drawn by the first zone 202 of the dual-zone heater 200. The current and voltage drawn by the first zone 202 may be measured using a resistance measuring device 218 capable of measuring the current and the voltage simultaneously. As used herein, simultaneously includes measurements made within the range of up to about 110 milliseconds of each other. In some embodiments, the resistance measuring device 218 may be a high frequency Hall effect current sensor (e.g., having an about 200 kHz or greater sampling rate) to capture the instantaneous current being delivered to the first zone 202 as well as the applied voltage.

For example, in some embodiments, the resistance measuring device 218 is coupled to the first power feed 212 to measure the current and voltage drawn by the first zone 202. The resistance measuring device 218 may also be coupled to the controller 112. In some embodiments, the resistance measuring device 218 and the controller 112 may be integrated (e.g., may be provided in the same housing or device).

Based on the measured current and voltage of the first zone 202, the controller 112 determines the resistance of the first zone 202 using Ohm's Law, which provides that resistance is equal to voltage divided by current (R=V/I). The controller 112 further determines the temperature of the first zone 202 based upon a predetermined relationship between the resistance and the temperature of the first zone 202. The simultaneous measurement of current and voltage are necessary to ensure the accuracy of the calculated resistance value. As the resistance of the heater is directly related to its temperature in a linear relationship, the accuracy of the resistance calculation is directly related to the accuracy of the temperature determination. In some embodiments, the resistance of the first zone 202 can be used to correlate the temperature of the first zone 202. The controller 112 further records the resistance measurement over a range of temperatures.

In some embodiments, the controller 112 may determine the temperature of the first zone 202 using an additional thermocouple (not shown) embedded in the first zone 202 of the pedestal 120.

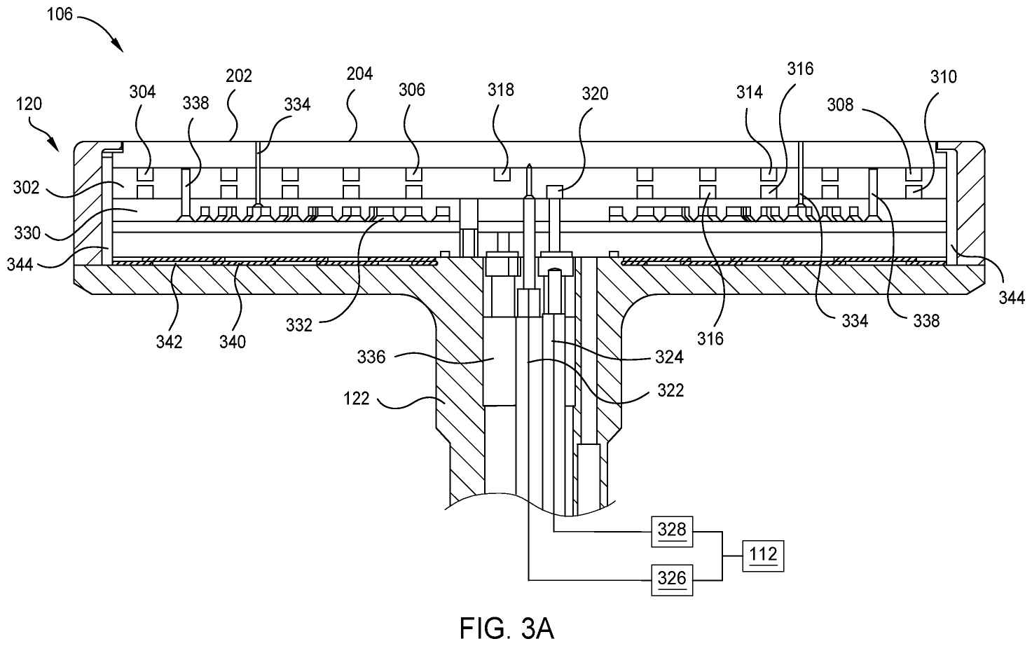

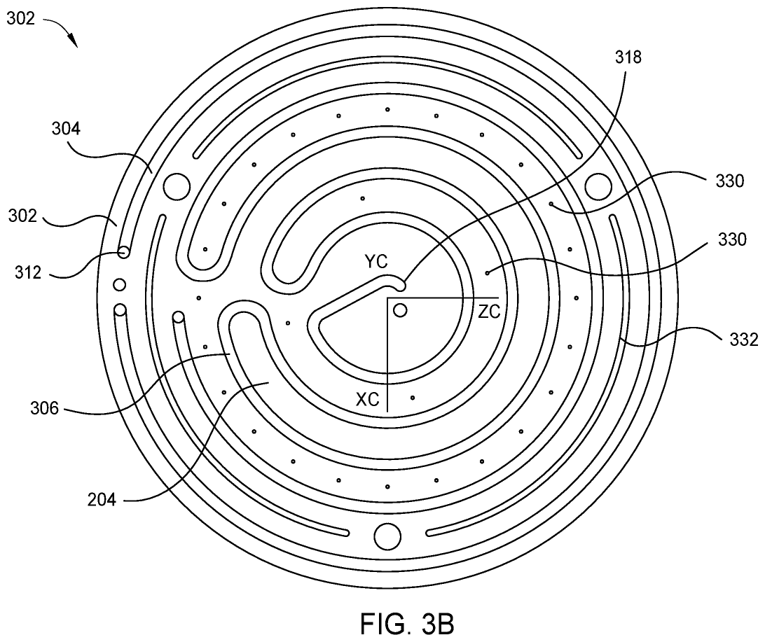

FIG. 3A depicts a side view of the substrate support assembly 106 that includes the dual-zone fast response pedestal 120 in accordance with some embodiments of the present invention. FIG. 3B depicts a top view of a chiller plate 302 within the dual-zone fast response pedestal 120 in accordance with some embodiments of the present invention. In some embodiments, the dual-zone fast response pedestal 120 has a first fluid channel 304 in the first zone 202 and a second fluid channel 306 in the second zone 204 embedded within the chiller plate 302. The first fluid channel 304 and the second fluid channel 306 are not in fluid communication with each other. The dual-zone fast response pedestal 120 includes a thermal conductive body, which may be a plurality of plates, including the chiller plate 302, that are brazed together to ensure heat transfer, or fabricated as a single component, for example, by lost foam casting or 3D printing. Each of the plurality of plates of the dual-zone fast pedestal 120 is fabricated from a thermally conductive material, such as a metal, e.g., aluminum. The first fluid channel 304 includes an upper portion 308 and a lower portion 310 between an inlet 312 (shown in FIG. 3B), an outlet (not shown). The lower portion 310 of the first fluid channel 304 may be disposed directly below or above the upper portion 308 of the first fluid channel 304. Alternatively, the lower portion 310 of first fluid channel 304 may be horizontally displaced from the upper portion 308 of the first fluid channel 304. Although FIGS. 3A and 3B show a single loop for the first fluid channel 304, any number of loops may be provided based on the channel orientation and dimensions as well as the pedestal dimensions. The second fluid channel 306 includes an upper portion 314 and a lower portion 316 between an inlet 318 and an outlet 320. The lower portion 316 of the second fluid channel 306 may be disposed directly below or above the upper portion 314 of the second fluid channel 306. Alternatively, the lower portion 316 of the second fluid channel 306 may be horizontally displaced from the upper portion 314 of the second fluid channel 306. As with the first fluid channel 304, the second fluid channel 306 may include any number of connected or spiraled loops around the second zone 204. In some embodiments, the second fluid channel 306 is arranged in a coil pattern as shown in FIG. 3B, but can alternatively be arranged in a spiral, or other geometric pattern for circulation of fluid.

The shaft 122 includes one or more of pairs of cooling tubes 322, 324. A first pair of cooling tubes 322 delivers and receives, respectively, a first heat exchange fluid to the first zone 202 of the pedestal 120 through the first fluid channel 304. A second pair of cooling tubes 324 delivers and receives, respectively, a second heat exchange fluid to the second zone 204 of the pedestal 120. In some embodiments, one of the first pair of cooling tubes 322 delivers the first heat exchange fluid through the inlet 312 and to the upper portion 308 of the first fluid channel 304 and circulated in the upper portion 308 of the first fluid channel 304. The first heat exchange fluid is then transferred to the lower portion 310 of the first fluid channel 304 where it is circulated in a reverse pattern in comparison to the upper portion 308 of the first fluid channel 304 to exit via the outlet (not shown) into the other of the first pair of cooling tubes 322. In some embodiments, one of the second pair of cooling tubes 324 delivers the second heat exchange fluid through the inlet 318 and to the upper portion 314 of the second fluid channel 306 at the center of the chiller plate 302 and delivered outwardly toward a distal position in the upper portion 314 of the second fluid channel 306. The second heat exchange fluid is then transferred to the lower portion 316 of the second fluid channel 306 where it is circulated in a reverse pattern of the upper portion 314 of the second fluid channel 306 back toward the of the chiller plate 302 to exit via the outlet 320 into the other of the second pair of cooling tubes 324.

The first and second heat exchange fluids may be the same or different fluids, and may be provided at the same or different temperatures in order to maintain the first and second zones 202, 204 at similar or different temperatures. The first pair of the cooling tubes 322 and the second pair of the cooling tubes 324 are fluidly coupled to respectively a first fluid source (not shown) connected to an inline heater 326 and a second fluid source (not shown) connected to an inline heater 328. The controller 112 adjusts the inline heaters 326, 328 to independently control the temperatures of the first heat exchange fluid and the second heat exchange fluid. For example, the first heat exchange fluid may be delivered at a temperature greater than or less than the second heat exchange fluid, which will allow the first zone 202 to be at a higher or lower, respectively, temperature than the second zone 204. Circulation of the heat exchange fluids allows the substrate temperature to be maintained at relatively low temperatures, e.g., about −20° C. to about 80° C., as well as at much higher temperatures. The temperatures may alternatively be maintained at between about 0° C. and 100° C. Exemplary heat exchange fluids include ethylene glycol and water, but other fluids may be utilized.

Alternatively, the temperature of the first zone 202 can be increased to be hotter than the temperature of the second zone 204. In some embodiments, the temperature of the first zone 202 can be adjusted to maintain a temperature differential between the first zone 202 and the second zone 204. For example, in some embodiments, the second zone 204 may be maintained at a higher temperature than the first zone 202, for example, by up to about 40 degrees hotter. In some embodiments, the second zone 204 may be maintained at a lower temperature than the first zone 202, for example, by up to about 15 degrees cooler. In some embodiments, the first zone 202 may be heated to a first temperature, for example about 90° C., and once the first temperature is reached, the second zone 204 may be heated to the desired second temperature. In some embodiments, once the second zone 204 is heated to the desired second temperature, the first and second zones 202, 204 may be ramped up together to a desired third temperature and/or fourth temperature.

The pedestal 120 further includes one or more purge channels within a purge plate 330 that is a plate disposed below the chiller plate 302 and brazed with the chiller plate 302 to provide the purge flow channels. For example, a first purge channel 332 may be defined by a portion of the purge plate 330. The first purge channel 332 may circulate a purge fluid throughout the pedestal 120 that is evacuated through a plurality of purge outlets 334 in the pedestal 120. Although FIG. 3A illustrates two purge outlet 334, any number of purge outlets may be included in different configurations.

The first purge channel 332 may be formed in any number of patterns within the pedestal 120. For example, the first purge channel 332 may be formed in a coil pattern throughout the pedestal 120 in order to provide thermal isolation between the pedestal 120 and the shaft 122 that may be heated with a heating element (not shown) such as a resistive heating element to maintain the shaft 122 at a particular temperature. Alternatively, a plurality of straight channels may be formed in the pedestal 120 that direct a purge fluid directly to the purge outlets 334. A purge fluid may be delivered from fluid tubes 336 in the shaft 122, through the first purge channel 332, and out through purge outlets 334. The purge fluid may be a gas, including an inert gas, which is utilized to limit or prevent the formation of process byproducts within holes or channels of the pedestal 120. When deposition and/or etch processes are performed, byproducts of the process will routinely condense on areas within the substrate processing chamber, including on the substrate support assembly 106. When these byproducts accumulate on and within the pedestal 120, a subsequent substrate positioned on the surface may tilt, which can result in non-uniform deposition or etching. A purge gas delivered through the pedestal 120 may be capable of dislodging and removing reactants from the pedestal 120.

The first purge channel 332 may additionally include a first isolation cavity 338, extending vertically through the purge plate 330 and the chiller plate 302, at a distal portion of the first purge channel 332. The first isolation cavity 338 may be located at the periphery of the first zone 202, and may be configured to receive a portion of the purge gas flow through the first purge channel 332, where the portion of purge gas is maintained in the first isolation cavity 338 to provide thermal isolation between the first zone 202 and the second zone 204. In some embodiments, multiple purge channels are included to separately deliver gas to the first isolation cavity 338 and the purge outlets 334. The channel or channels coupled with the first isolation cavity 338 may be outwardly closed, such that the channel may be pressurized with fluid. A pressurized gas or pressurized fluid may be delivered to the first isolation cavity 338, or pressurized within the first isolation cavity 338 to provide a barrier or temperature barrier at the location of the first isolation cavity 338. The first isolation cavity 338 may be arranged as a channel that may separate the first and second zones 202, 204 around the entire pedestal 120. The purge gas or fluid may be heated or cooled to be delivered to the first isolation cavity 338 such that it does not affect the temperature control of the heat exchange fluids being circulated in the pedestal 120. Alternatively, the purge gas may be delivered at a temperature selected to adjust the temperature profile across the pedestal 120.

Since the first isolation cavity 338 extends through the chiller plate 302 and purge plate 330, the first isolation cavity 338 may create a thermal barrier between the first and second fluid channels 304, 306, and between the first zone 202 and the second zone 204 of the pedestal 120.

The pedestal 120 may also include a second purge channel 340 that may be defined along an interface between the shaft 122 and the pedestal 120. The second purge channel 340 may be configured to provide a second purge flow path for a purge gas that may produce an additional thermal barrier between the shaft 122 and the pedestal 120. Accordingly, heat applied to the shaft 122 to limit the amount of deposition of process byproducts may not affect the temperature control scheme applied through the pedestal 120. The second purge channel 340 may additionally include a second isolation cavity 342 and a purge outlet 344. The second isolation cavity 342 and the purge outlet 344 may be configured to receive a portion of purge gas delivered through the second purge channel 340, and may provide additional thermal isolation between the edge of the pedestal 120, and the second zone 204 of the pedestal 120. Accordingly, the interface of the pedestal 120 and the shaft 122 may be heated in a fashion similar to the shaft 122 in order to reduce the amount of byproduct deposition on the equipment, while providing a barrier to the pedestal 120 such that a uniform temperature profile may be more readily provided on the pedestal 120 in the second zone 204.

The second isolation cavity 342 may function and be arranged in a similar fashion as the first isolation cavity 338. Purge gas or fluid may be delivered through the second purge channel 340 from the same fluid tubes 336 in the shaft 122 as those delivering purge gas to the first purge channel 332, or may be delivered through different fluid tubes in the shaft 122. The purge gas delivered to the first and second purge channels 332, 340 may be the same or different. The purge gas may be delivered through the second purge channel 340 and into the second isolation cavity 342, prior to being expelled through the purge outlet 344 at the top of the second isolation cavity 342. The purge outlet 344 at the top of second isolation cavity 342 may be similar to the purge outlets 334 through which the first purge gas is delivered. Alternatively, a space may be created around the entirety of the top of the second isolation cavity 342 for the flow of purge gas. Alternatively, the second isolation cavity 342 may be outwardly closed such that fluid buildup or pressurization may be performed in the second isolation cavity 342 providing an enhanced thermal barrier at the external edge of the pedestal.

In some embodiments, the controller 112 determines the temperature of the first zone 202 and the second zone 204 and adjust the temperatures of the first and second heat exchange fluids at a frequency of between about 60 Hz and 90 Hz. Response time (i.e., the time required for the temperatures of the first zone 202 and the second zone 204 to reach the respective target temperatures) is less than 60 seconds.

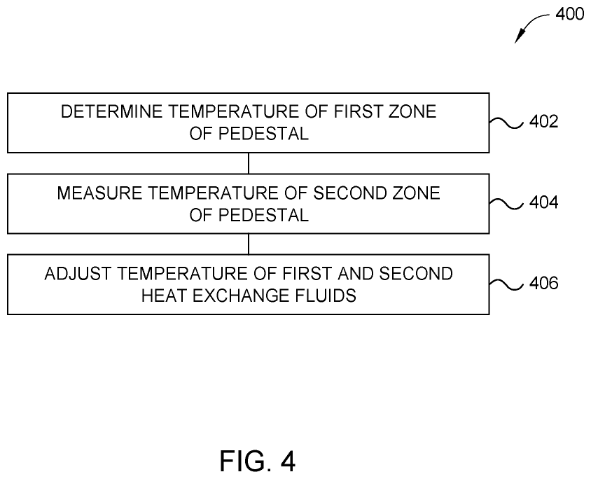

FIG. 4 is a flow diagram of one embodiment of a method 400 for controlling the temperature of a substrate supporting surface of the dual-zone fast response pedestal 120. The method 400 begins at block 402, by determining the temperature of an inner zone of the pedestal 120.

In block 404, the temperature of the second zone 204 is measured using a thermocouple 216.

In block 406, based on the determined temperature of the first zone 202 and the measured temperature of the second zone 204, the controller 112 adjusts heating and cooling of the first zone 202 and the second zone 204, by determining target temperatures of the first zone 202 and the second zone 204 and adjusting temperatures of a first heat exchange fluid to be circulated in the first zone 202 and a second heat exchange fluid to be circulated in the second zone 204.

In the example embodiments described above, the method and the system are provided to control the temperature profile of a dual-zone heated substrate support (and thus, a substrate disposed thereon) to be uniform, or to be controllably non-uniform. For example, in some embodiments, a uniform thermal profile may be provided. Alternatively, a center cold profile or a center hot profile may be provided.

While certain embodiments have been described, these embodiments have been presented by way of example only, and are not intended to limit the scope of the inventions. Indeed, the novel embodiments described herein may be embodied in a variety of other forms. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate support pedestal connectable to a shaft, comprising:
a thermally conductive body;
a first fluid channel disposed within an outer zone of the thermally conductive body; and
a second fluid channel disposed within an inner zone of the thermally conductive body, wherein the first fluid channel and the second fluid channel are not in fluid communication with each other and are thermally isolated from each other by a thermal barrier within the substrate support pedestal.

2. The substrate support pedestal of claim 1, wherein
the thermally conductive body comprises aluminum.

3. The substrate support pedestal of claim 1, further comprising:
a ceramic coating on a top surface of the thermally conductive body, wherein the substrate support pedestal is configured to support a substrate to be processed on the top surface of the substrate support pedestal.

4. The substrate support pedestal of claim 3, wherein the ceramic coating comprises aluminum oxide.

5. The substrate support pedestal of claim 1, further comprising:
a first heating element disposed within the outer zone of the thermally conductive body; and
a second heating element disposed within the inner zone of the thermally conductive body.

6. The substrate support pedestal of claim 1, further comprising:
a plurality of purge channels configured to circulate a purge fluid throughout the thermally conductive body, wherein
the plurality of purge channels are each in fluid communication with an outlet formed within the substrate support pedestal.

7. A substrate support pedestal assembly, comprising:
a shaft comprising a first pair of cooling tubes and a second pair of cooling tubes, wherein the first pair of cooling tubes are configured to be fluidly coupled to a first heated fluid source and the second pair of cooling tubes are configured to be fluidly coupled to a second heated fluid source; and
a substrate support pedestal coupled to the shaft, the substrate support pedestal comprising a first fluid channel in fluid communication with the first pair of cooling tubes and a second fluid channel in fluid communication with the second pair of cooling tubes, wherein:
the first fluid channel is configured to circulate a first heat exchange fluid at a first temperature in an outer zone of the substrate support pedestal, and
the second fluid channel is configured to circulate a second heat exchange fluid at a second temperature that is different from the first temperature in an inner zone of the substrate support pedestal disposed within the outer zone.

8. The substrate support pedestal assembly of claim 7, wherein
the substrate support pedestal comprises a thermally conductive body.

9. The substrate support pedestal assembly of claim 8, wherein
the thermally conductive body comprises aluminum.

10. The substrate support pedestal assembly of claim 7, further comprising:
a ceramic coating on a top surface of the substrate support pedestal, wherein the substrate support pedestal is configured to support a substrate to be processed on the top surface of the substrate support pedestal.

11. The substrate support pedestal assembly of claim 10, wherein the ceramic coating comprises aluminum oxide.

12. The substrate support pedestal assembly of claim 7, further comprising:
a first heating element disposed within the outer zone of the substrate support pedestal; and
a second heating element disposed within the inner zone of the substrate support pedestal.

13. The substrate support pedestal assembly of claim 7, wherein the substrate support pedestal further comprises:
a plurality of purge channels that circulate a purge fluid throughout the substrate support pedestal, wherein
the plurality of purge channels are each in fluid communication with a cooling tube disposed within the shaft and an outlet formed within the substrate support pedestal.

14. A processing chamber, comprising:
a chamber body;
a shaft disposed within the chamber body, the shaft comprising a first pair of cooling tubes and a second pair of cooling tubes, wherein the first pair of cooling tubes are configured to be fluidly coupled to a first heated fluid source and the second pair of cooling tubes are configured to be fluidly coupled to a second heated fluid source;
a substrate support pedestal disposed within the chamber body and coupled to the shaft, the substrate support pedestal comprising a first fluid channel disposed within an outer zone of the substrate support pedestal and in fluid communication with the first pair of cooling tubes and a second fluid channel disposed within an inner zone of the substrate support pedestal in fluid communication with the second pair of cooling tubes, wherein:
the first fluid channel is configured to circulate a first heat exchange fluid at a first temperature in an outer zone of the substrate support pedestal, and
the second fluid channel is configured to circulate a second heat exchange fluid at a second temperature that is different from the first temperature in an inner zone of the substrate support pedestal disposed within the outer zone; and
a controller configured to:
determine temperatures of the outer zone and the inner zone of the substrate support pedestal, and
adjust the first temperature and the second temperature based on the determined temperatures of the outer zone and the inner zone of the substrate support pedestal.

15. The processing chamber of claim 14, wherein
the substrate support pedestal comprises a plurality of thermally conductive plates that are brazed together.

16. The processing chamber of claim 15, wherein
the plurality of thermally conductive plates comprise aluminum.

17. The processing chamber of claim 14, further comprising:
a ceramic coating on a top surface of the substrate support pedestal, wherein the substrate support pedestal is configured to support a substrate to be processed on the top surface of the substrate support pedestal.

18. The processing chamber of claim 17, wherein the ceramic coating comprises aluminum oxide.

19. The processing chamber of claim 14, wherein the substrate support pedestal further comprises:
a first heating element disposed within the outer zone of the substrate support pedestal; and
a second heating element disposed within the inner zone of the substrate support pedestal.

20. The processing chamber of claim 14, wherein the substrate support pedestal further comprises:
a plurality of purge channels that circulate a purge fluid throughout the substrate support pedestal, wherein
the plurality of purge channels are each in fluid communication with a cooling tube disposed within the shaft and an outlet formed within the substrate support pedestal.
